(19) United States
(12) Patent Application Publication
(10) Pub. No.: US 2013/0026508 A1
(43) Pub. Date: Jan. 31, 2013

(54) LED MODULE WITH PASSIVE LED

(71) Applicant: Tobias Roos, Villingen-Schwenningen (DE)

(72) Inventor: Tobias Roos, Villingen-Schwenningen (DE)

(21) Appl. No.: 13/640,389

(22) PCT Filed: Apr. 2, 2011
(86) PCT No.: PCT/EP2011/001666

§ 371 Date: Oct. 10, 2012

(30) Foreign Application Priority Data
Apr. 11, 2010 (DE) 20 2010 004 874.5

(51) Int. Cl. H01L 33/58

(52) U.S. Cl. 257/88; 257/E33.073

(57) ABSTRACT

An LED module (1) includes a plurality of LEDs (76 to 89) which are arranged on a printed circuit board (75) and which each have a “bedding element” with a lens (100 to 113) with which the respective LED (76 to 89) protrudes from the printed circuit board plane. The LEDs (76 to 89) are each coupled to a light input element of an optical waveguide body and the respective associated light input element radiates the respective luminous flux from the associated LED (76 to 89) outwards from the LED module (1). To achieve a homogeneous external appearance, the printed circuit board (75) for the LEDs (76 to 89) has at least one passive LED (95, 96, 97) provided thereon.

### CROSS REFERENCE TO RELATED APPLICATIONS

This application is a United States National Phase application of International Application PCT/EP2011/001666 and claims the benefit of priority under 35 U.S.C. §119 of DE 20 2010 004 874.5 filed Apr. 11, 2010, the entire contents of which are incorporated herein by reference.

### FIELD OF THE INVENTION

The invention relates to an LED module comprising a plurality of LEDs which are arranged on a printed circuit board and which each have a “bedding element” with a lens with which the respective LED protrudes from the printed circuit board plane, wherein the LEDs are each coupled to a light input element of an optical waveguide body and the respective associated light input element radiates the respective luminous flux from the associated LED outwards from the LED module.

### BACKGROUND OF THE INVENTION

LED modules comprising a plurality of LEDs arranged on a printed circuit board have been known for some time. An LED of this kind comprises an anode connection, a cathode connection and a “cup” into which an LED crystal has been inserted. The LED crystal is connected to the anode connection by means of a bonding wire. To protect both the cathode connection and the anode connection and also the LED crystal, these components are embedded in a “bedding element”, which usually comprises a plastic. The bedding element usually forms a kind of lens, so that the beam of light emitted by the LED crystal is radiated over as large an area as possible in order to reduce a dazzle effect for the observer as far as possible.

Since such LEDs now have a light intensity which is even sufficient for illumination purposes, there has recently been an increasing trend towards using such LEDs even for lamps of a wide variety of types. In particular, it is known practice to arrange such LEDs in a matrix-like multiple arrangement on a printed circuit board in order to achieve sufficient luminosity.

Although the life of such LEDs is stated as being several thousand hours, it can nevertheless be observed that individual LEDs in an LED module can fail prematurely. If a plurality of LEDs are provided, the failure of one LED is normally negligible with regard to the total luminous power of the overall LED module. However, the failure of an LED is outwardly discernable when looking at the LED module and in the first instance disturbs the external appearance of the LED module. Although the luminosity of the LED module is still adequate when one LED fails, the LED module is nevertheless replaced, which means that unnecessary costs arise in this case.

### SUMMARY OF THE INVENTION

Accordingly, the invention is based on an object of providing an LED module comprising a plurality of LEDs arranged on a printed circuit board, in which the failure of single LEDs is not outwardly apparent. The invention together achieves this object by virtue of the printed circuit board for the LEDs having at least one passive LED provided on it which can be activated if one of the LEDs fails, and by virtue of the luminous flux emitted by the passive LED shining into the light input element of the respective LED and being radiated outwards by the light input element.

As a result of this configuration, the “input” of the luminous flux emitted by the passive LED into the light input element of the failed LED means that the latter appears to continue to be lit, so that the overall visual impression of the LED module is not disturbed.

In addition, according to a further aspect of the invention, provision may be made for a plurality of passive LEDs to be provided which are associated with a plurality of LEDs with the light input elements thereof and for the respective passive LED to be able to be activated if one of the respective associated LEDs fails. This configuration allows the number of passive LEDs to be used to be reduced to a minimum In this case, the respective passive LEDs are preferably arranged between the LEDs which are arranged in a matrix, so that the luminous flux can reach a plurality of light input elements of the surrounding LEDs at the same time and hence a plurality of light input elements can be supplied with the requisite luminous flux by a single passive LED at the same time.

The various features of novelty which characterize the invention are pointed out with particularity in the claims annexed to and forming a part of this disclosure. For a better understanding of the invention, its operating advantages and specific objects attained by its uses, reference is made to the accompanying drawings and descriptive matter in which preferred embodiments of the invention are illustrated.

### BRIEF DESCRIPTION OF THE DRAWINGS

In FIG. 1 is a perspective plan view of a printed circuit board with mounted LEDs and a plurality of passive LEDs arranged between the LEDs; and

FIG. 2 is a sectional illustration II-II from FIG. 1 of a fully mounted LED module which is used as a light source.

### DESCRIPTION OF THE PREFERRED EMBODIMENTS

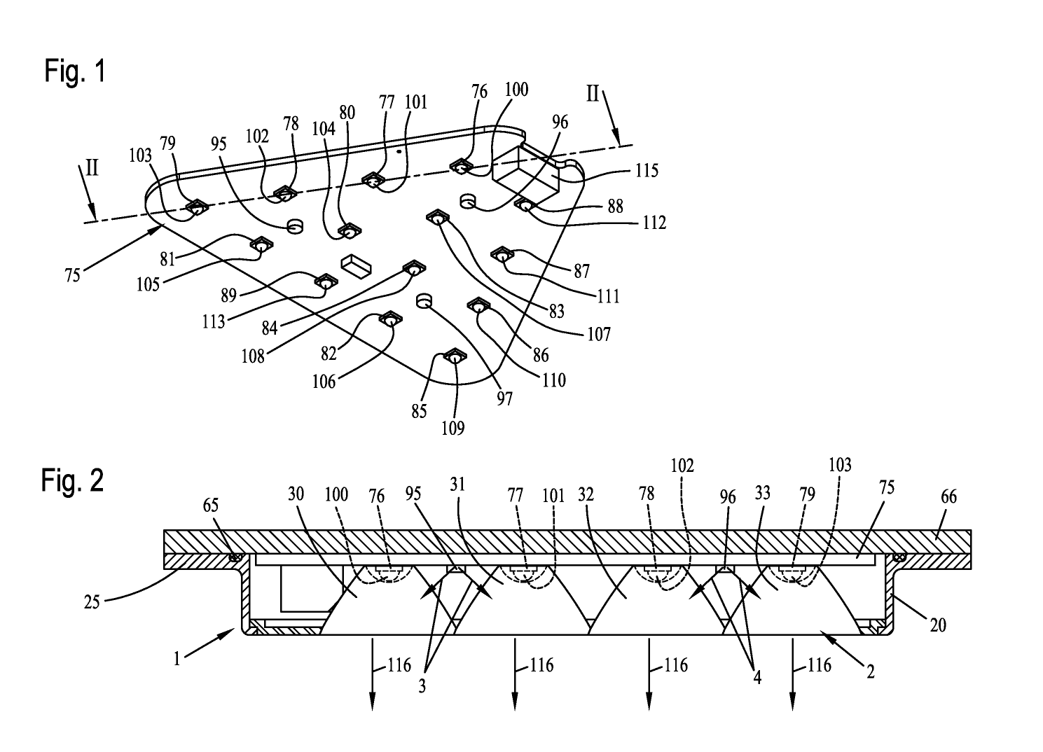

Referring to the drawings in particular, FIG. 1 shows an example of a possible variant embodiment of a printed circuit board 75 which is equipped with a plurality of LEDs 76, 77, 78, 79, 80, 81, 82, 83, 84, 85, 86, 87, 88, 89 which are arranged in a matrix. Each of these LEDs 76 to 89 is respectively provided with an outwardly protruding lens 100, 101, 102, 103, 104, 105, 106, 107, 108, 109, 110, 111, 112 and 113 which, in the state in which it has been inserted into an LED module 1, respectively protrudes into a light input element 30, 31, 32, 33 of an optical waveguide body 2, as can be seen for the LEDs 76, 77, 78 and 79 from FIG. 2.

In the present exemplary embodiment, a total of three passive LEDs 95, 96 and 97 are provided. In the present case, the passive LED 95 is associated with the LEDs 78, 79, 80, 81, 89, so that a luminous flux emitted by the passive LED 95 can reach the adjacent LEDs 78, 79, 80, 81, 89. In the same way, the passive LED 96 is associated with the LEDs 76, 77, 83, 87, 88, while the passive LED 97 is associated with the LEDs 82, 84, 85, 86.

Furthermore, FIG. 1 shows that the printed circuit board 75 is provided with a schematically shown electrical connector 115 in the region of the LEDs 76 and 88, the electrical connector being able to be used to supply the requisite power to all the LEDs 76 to 89 collectively.

In respect of the operation of the passive LEDs 95, 96 and 97, FIG. 2 shows a simplified sectional illustration II-II from FIG. 1 of a mounted LED module 1. On account of the section orientation, FIG. 2 accordingly reveals only the LEDs 76, 77, 78 and 79—arranged on the printed circuit board 75—with the lenses 100, 101, 102 and 104 thereof and also the passive LEDs 95 and 96 arranged “between” the LEDs.

In the mounted state, the respective lenses 100, 101, 102, 103, of spherically curved design, of the LEDs 76, 77, 78, 79 protrude into the respective associated light input element 30, 31, 32, 33 in a defined manner, so that the luminous flux entering the light input elements 30, 31, 32, 33 is radiated outwards, for example essentially parallel, through the light input elements 30, 31, 32, 33 essentially in the direction of the arrow 116.

As can be seen from FIG. 2, the printed circuit board 75 in the LED module 1 is held between an optical waveguide body 2 and a housing plate 66. In the present case, the optical waveguide body 2 has its underside statically mounted on the housing plate 66 by means of a mounting frame 20 and can be detachably bolted to the housing plate, for example. A seal 65 has been inserted in the region of the mounting flange 25 of the mounting frame 20, and therefore the mounting frame 20 is fully circumferentially sealed from the housing plate 66 by means of the seal 65. The mounting frame 20 and the optical waveguide body 2 may also be of integral design. In addition, it can be seen that the lenses 100, 101, 102, 103 of the LEDs 76, 77, 78 and 79 protrude into the respective associated light input element 30, 31, 32 and 33. The light input elements 30, 31, 32, 33 therefore radiate the light beams emitted in cone form by the LEDs 76 to 79 or the lenses 100 to 103 thereof vertically downwards in the direction of the arrow 116 essentially to form a uniform luminous flux.

If one of the LEDs 76, 77, 78 or 79 now fails, one of the passive LEDs 95 and 96 accordingly associated with the LEDs 76, 77 and 78, 79 can be activated by means of appropriate actuation. Depending on which of the LEDs 76, 77, 78 and 79 has failed, a luminous flux is accordingly shone into the light input elements 30, 31 or 32, 33 in the direction of the arrow 3 or 4 and deflected outwards by the light input elements in the direction of the arrow 116.

The relevant LED or the relevant light input element 31, 32 or 32, 33 therefore has the outward appearance of continuing to be lit, so that the external appearance of the LED module 1 is not disturbed.

It is therefore not possible to recognize—or only the trained eye of an observer is able to recognize—on the outside that one of the LEDs 76, 77, 78 and 79 has failed. A further advantage of this configuration is that the passive LEDs 95, 96 and 97 can be operated at much lower power than the high-power LEDs 76 to 89 from FIG. 1. It is therefore possible to simulate the operability of a failed LED with extremely little power involvement.

While specific embodiments of the invention have been shown and described in detail to illustrate the application of the principles of the invention, it will be understood that the invention may be embodied otherwise without departing from such principles.

1. A LED module comprising:
a printed circuit board;
a plurality of LEDs which are arranged on the printed circuit board and which each have a bedding element with a lens with which the respective LED protrudes from a printed circuit board plane;
an optical waveguide body with a plurality of light input elements, wherein the LEDs are each coupled to an associated one of the light input elements of the optical waveguide body and the respective associated light input element radiates a respective luminous flux from the associated LED outwards from the LED module; and
a passive LED provided on the printed circuit board which can be activated if one of the plurality of LEDs fails, and in that a luminous flux emitted by the passive LED shines into the light input element of the respective LED and is radiated outwards by the light input element.

2. A LED module according to claim 1, wherein:
a plurality of passive LEDs are provided which are associated with the plurality of LEDs with the light input elements thereof and in that the respective passive LED can be activated if one of the respective associated LEDs fails.

3. A LED module comprising:
a printed circuit board;
a plurality of LEDs which are arranged on the printed circuit board and which each have a lens which protrudes from a printed circuit board plane;
an optical waveguide body with a plurality of light input elements, wherein the plurality of LEDs are each coupled to an associated one of the light input elements of the optical waveguide body and the respective associated light input element radiates a respective luminous flux from the associated LED outwards from the LED module; and
a passive LED provided on the printed circuit board which is activated upon a failure of the plurality of LEDs and emits a passive LED luminous flux that shines into at least one of the light input elements is radiated outwards by the at least one of the light input element.

4. A LED module according to claim 1, further comprising additional passive LEDs to provide a plurality of passive LEDs wherein each of said plurality of passive LEDs is associated with one of said plurality of LEDs and is associated with one of the light input elements thereof and a respective associated passive LED is activated upon the failure of the respective associated LED.
